(19) United States
(12) Patent Application Publication
(10) Pub. No.: US 2025/0279349 A1
(43) Pub. Date: Sep. 4, 2025

(54) CAPACITIVE JUNCTION BETWEEN CONDUCTIVE LINE AND CONDUCTIVE PILLAR WITH METHODS TO FORM SAME

(71) Applicant: GlobalFoundries U.S. Inc., Malta, NY (US)

(72) Inventors: Kiril Biserov Borisov, Sofia (BG); Olga Keplinger, Weinböhla, Saxony (DE); Michael Grillberger, Radebeul (DE); Jhnanesh Somayaji, Bangalore (IN); Binit Syamal, Dresden (DE); Tom Herrmann, Dresden (DE); Iva Stoyanova Gurgutova, Sofia (BG); Boris Danailov Dobrichkov, Sofia (BG); Benoit Francois Claude Ramadout, Dresden (DE)

(21) Appl. No.: 18/594,074

(22) Filed: Mar. 4, 2024

(51) Int. Cl. H01L 23/522; H01L 21/768; H01L 23/528

(52) U.S. Cl. CPC H01L 23/5223; H01L 21/76829; H01L 23/5283

(57) ABSTRACT

Structures of the disclosure include a first conductive line within a dielectric material. The dielectric material extends over the first conductive line. A second conductive line is within the dielectric material and substantially vertically aligned with the first conductive line. A conductive pillar is within the dielectric material between the first conductive line and the second conductive line. The conductive pillar includes an upper surface contacting a lower surface of the second conductive line or a lower surface contacting an upper surface of the first conductive line. A vertical thickness of the conductive pillar is less than a vertical thickness between the first conductive line and the second conductive line. a first capacitive junction is between the conductive pillar and one of the first conductive line and the second conductive line. A second capacitive junction is between the conductive pillar and a horizontally adjacent conductive pillar.

### BACKGROUND

The present disclosure relates to integrated circuit structures and, more particularly, to conductive lines of integrated circuit structures.

Capacitors are used in a wide variety of integrated circuits (ICs). As ICs have scaled smaller, forming capacitors has become more challenging. Although it is possible to form capacitors in the metal wiring layers of a device (i.e., the “back end of line” (BEOL) layers), these structures conventionally will occupy significant chip area to achieve desired amounts of capacitance. Some implementations of capacitors in metal wiring layers may require, e.g., forming additional, dedicated capacitor dielectric layers for the various capacitor devices to operate. Such techniques undesirably increase the number of masks and/or processing phases to form a device.

### SUMMARY

All aspects, examples and features mentioned below can be combined in any technically possible way.

An aspect of the disclosure provides a structure including: a first conductive line within a dielectric material, the dielectric material extending over the first conductive line; a second conductive line within the dielectric material and substantially vertically aligned with the first conductive line; and a conductive pillar within the dielectric material between the first conductive line and the second conductive line, wherein the conductive pillar includes one of an upper surface contacting a lower surface of the second conductive line and a lower surface contacting an upper surface of the first conductive line, wherein a vertical thickness of the conductive pillar is less than a vertical thickness between the first conductive line and the second conductive line, a first capacitive junction is between the conductive pillar and one of the first conductive line and the second conductive line, and a second capacitive junction is between the conductive pillar and a horizontally adjacent conductive pillar.

An aspect of the disclosure includes a structure, including: a first plurality of conductive lines within a dielectric material, each of the first plurality of conductive lines having an alternating polarity relative to an adjacent conductive line of the first plurality of conductive lines; a second plurality of conductive lines on the dielectric material and substantially vertically aligned with the first plurality of conductive lines, each of the second plurality of conductive lines having an alternating polarity relative to an adjacent conductive line in the second plurality of conductive lines; and a plurality of conductive pillars within the dielectric material, wherein each of the plurality of conductive pillars includes one of an upper surface interfacing with a lower surface of the second plurality of conductive lines and a lower surface interfacing with an upper surface of the first plurality of conductive lines conductive line, a vertical thickness of each conductive pillar is less than a vertical thickness between the plurality of first conductive lines and the plurality of second conductive lines, a first capacitive junction is between each conductive pillar and the first plurality of conductive lines or the second plurality of conductive lines, and a second capacitive junction is between two horizontally adjacent conductive pillars of the plurality of conductive pillars.

An aspect of the disclosure includes a method, including: forming a first conductive line within a dielectric material; forming a conductive pillar within the dielectric material over the first conductive line,, wherein a vertical thickness of the conductive pillar is less than a vertical thickness of the dielectric material between the first conductive line and the second conductive line; and forming a second conductive line on the dielectric material and the conductive pillar above the first conductive line, wherein the second conductive line is substantially aligned with the first conductive line, a first capacitive junction is between the conductive pillar and one of the first conductive line and the second conductive line, and a second capacitive junction is between the conductive pillar and a horizontally adjacent conductive pillar.

Two or more aspects described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a perspective view of a structure according to embodiments of the disclosure.

FIG. 2 shows a cross-sectional view of a structure according to embodiments of the disclosure.

FIG. 3 shows a perspective view of a structure with an additional etch stop material according to embodiments of the disclosure.

FIG. 4 shows a perspective view of a structure with multiple additional etch stop materials according to embodiments of the disclosure.

FIG. 5 shows a perspective view of a structure with multiple conductive pillars according to embodiments of the disclosure.

FIG. 6 shows a perspective view of a structure with multiple conductive pillars and an additional etch stop material according to embodiments of the disclosure.

FIG. 7 shows a perspective view of a structure with multiple conductive pillars and multiple additional etch stop materials according to embodiments of the disclosure.

FIG. 8 shows a perspective view of a structure with conductive pillars on conductive lines according to embodiments of the disclosure.

FIG. 9 shows a perspective view of a structure with multiple conductive pillars on each conductive line according to embodiments of the disclosure.

FIGS. 10-12 depicts processes of a method to form capacitive junctions between a conductive line and conductive pillar according to embodiments of the disclosure.

FIGS. 13-24 depicts various processes in methods to form capacitive junctions between a conductive line and conductive pillar according to further embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure provide a structure and method to provide capacitive junctions between a conductive line and conductive pillar. Structures of the disclosure include a first conductive line within a dielectric material. The dielectric material extends over the first conductive line. A second conductive line is within the dielectric material and substantially vertically aligned with the first conductive line. A conductive pillar is within the dielectric material between the first conductive line and the second conductive line. The conductive pillar includes an upper surface contacting a lower surface of the second conductive line or a lower surface contacting an upper surface of the first conductive line. A vertical thickness of the conductive pillar is less than a vertical thickness between the first conductive line and the second conductive line. A first capacitive junction is between the conductive pillar and one of the first conductive line and the second conductive line. A second capacitive junction is between the conductive pillar and a horizontally adjacent conductive pillar. As a result, portions of existing dielectric material (e.g., inter-level dielectric (ILD) layer, etch stop layer (ESL) material, etc.) provide capacitive junctions. Through embodiments of the disclosure, a circuit fabricator can omit one or more conventional capacitor structures on a device layer, as well as any intermediate isolating or intercoupling components that would otherwise be needed to provide the desired operational characteristics.

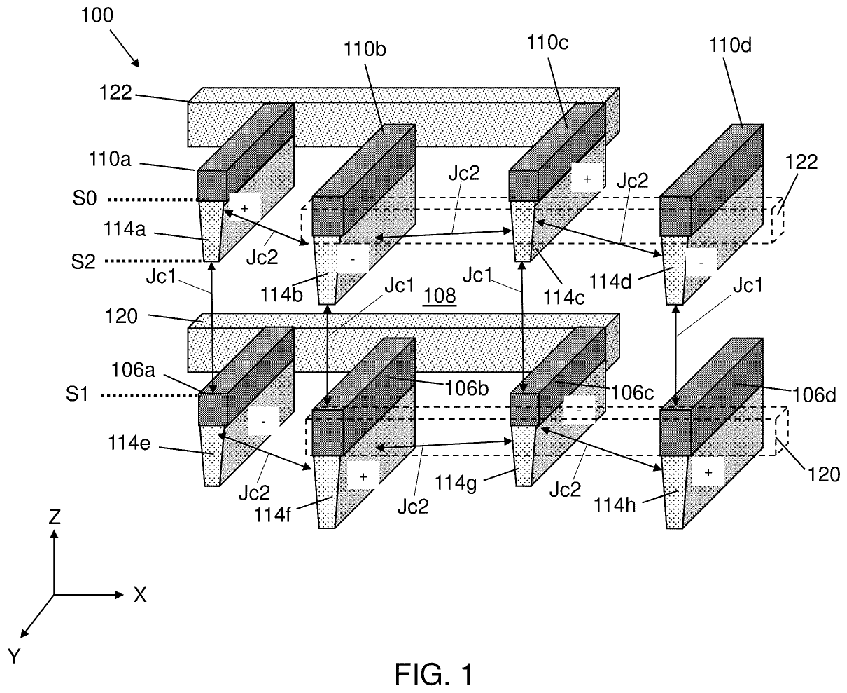

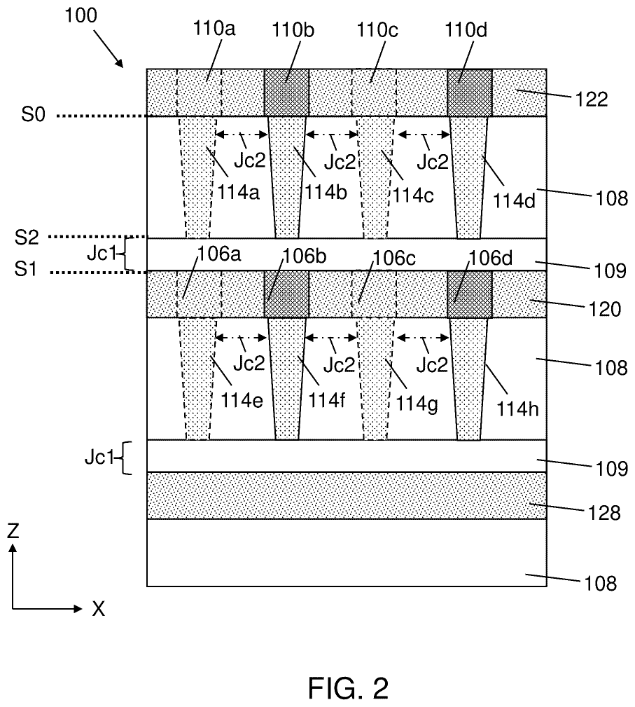

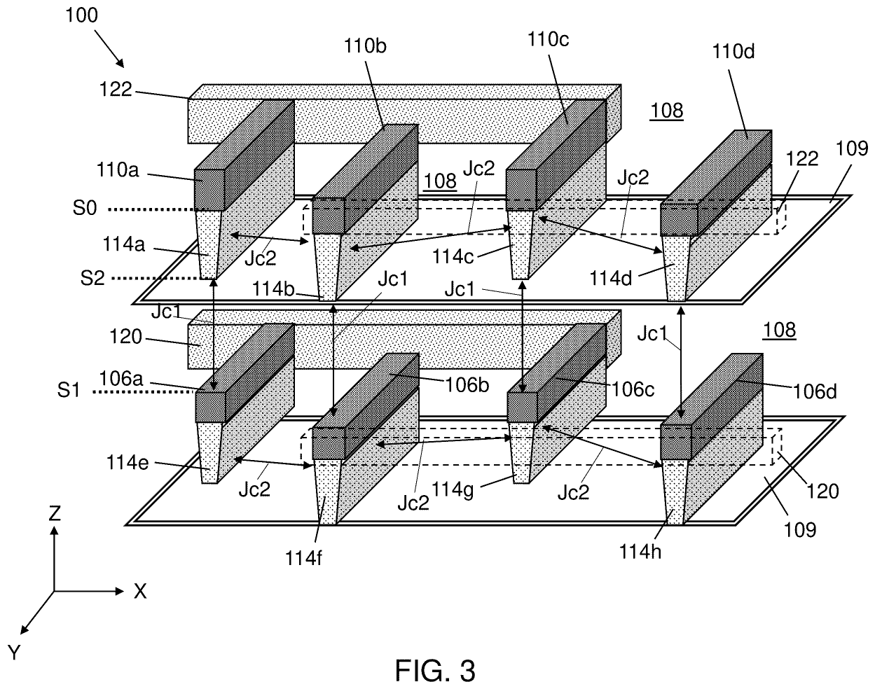

Referring to FIGS. 1 and 2, in which FIG. 1 provides a perspective view and FIG. 2 provides a cross-sectional view in plane X-Z, of a structure 100 to provide capacitive junctions between a conductive pillar and a conductive line according to embodiments of the disclosure. Structure 100 may be, e.g., within metal wiring layers (also known as “back end of line” (BEOL) layers) of a device. Structure 100 may include one or more first conductive lines 106 (four 106a-d shown in FIG. 1, four 106a-d shown in FIG. 2) within a dielectric material 108. Any of the illustrative first conductive lines 106 may be referenced separately as first conductive line 106a, 106b, 106c, 106d, and are collectively referenced as “first conductive lines 106.” Dielectric material 108 may include any currently known or later developed insulative substance, including for instance oxide-based insulators (e.g., various silicon oxide compounds), nitride based insulators, and/or other insulative materials particularly those having a dielectric constant of less than approximately 3.9.

Where structures 100 are provided within metal wiring layers of a device, dielectric material 108 may include an inter-level dielectric (ILD) layer for separating different layers from each other. In this case, portions of dielectric material 108 may include etch stop layers (ESL) 109 (shown in FIG. 2, also FIGS. 3, 4, 6, 7 discussed herein). ESL 109 may include, e.g., any material distinct from dielectric material 108 and having greater resistance to etching, to structurally distinguish between vertically adjacent wiring layers. As discussed elsewhere herein, ESLs 109 may be structurally distinct from dielectric material 108 and may be formed in a variety of configurations for additional electrical and physical separation between electrically active conductive materials. In some cases, ESL 109 may include an insulative material. In other cases, ESL 109 may include one or more conductive materials, e.g., to provide and/or maintain alternating polarity between the conductive lines 106a, 106b, 106c, 106d.

Each first conductive line 106 within dielectric material 108 may include any currently known or later developed conductive metal suitable to accumulate charge across a dielectric junction. First conductive line 106, in one example, may include silicon-based conductors materials or other doped semiconductor conductive materials capable of operating as a capacitor terminal. In further embodiments, first conductive line 106 may include one or more metals, e.g., tungsten (W), titanium (Ti), ruthenium (Ru), cobalt (Co), copper (Cu), aluminum (Al), etc. First conductive lines 106 may be formed by depositing conductive materials on an underlying layer (e.g., another layer of dielectric material) e.g., dielectric material 108 is formed thereon. First conductive lines 106 in different positions may be electrically decoupled from each other, e.g., they may be isolated from each other by portions of dielectric material 108. Multiple first conductive lines 106 may be present in structure 100 to provide alternating polarity terminals of distinct capacitive junctions as discussed herein.

Structure 100 also includes one or more second conductive lines 110 within dielectric material 108. Portions of dielectric material 108 with second conductive line(s) 110 therein may constitute a different layer of dielectric material 108 from where first conductive lines 106 are positioned. Any of the illustrative second conductive lines 110 may be referenced separately as second conductive line 110a, 110b, 110c, 110d, and are collectively referenced as “second conductive lines 110.” Second conductive lines 110 may include the same or similar example material(s) as first conductive line(s) 106. Thus, each first conductive line 106 and each second conductive line may include Cu or any metal(s) discussed herein. Each second conductive line 110 is substantially vertically aligned with, or otherwise directly over, a respective first conductive line 106. First conductive lines 106 and second conductive lines 110 may be separated from each other by a vertical distance that is large enough to prevent any direct coupling between conductive lines 106, 110, e.g., such that distinct conductive wires of a product will not electrically interfere with each other and/or produce electrical shorting as a device operates.

Embodiments of structure 100 include a set of first capacitive junctions Jc1 in selected locations by providing one or more conductive pillars 114 to first conductive line(s) 106 and/or second conductive line(s) 110 that do not completely traverse the vertical distance (of dielectric layer 108) between conductive lines 106, 110. That is, each conductive pillar 114 protrudes vertically through only a portion of the vertical thickness of dielectric layer 108 between conductive lines 106, 110 and thus does not provide a vertical interconnect (“via”) between each pair of substantially vertically aligned conductive lines 106, 110. Furthermore, embodiments of structure 100 also include a set of second capacitive junctions Jc2 across dielectric layer between horizontally adjacent conductive pillars 114 within the same wiring level. Conductive pillars 114 may have the same composition or similar compositions to conductive lines 106, 110. In the case where first conductive lines 106 and second conductive lines 110 include Cu, conductive pillars may include a metal or other conductive material composition different from Cu, e.g., other conductive semiconductor materials (e.g., doped Si or silicon germanium (SiGe), metals such aluminum, (Al), copper (Cu), zinc (Zn), gold (Au), and/or other conductive materials. Conductive pillars 114 each may include refractory metal liners (not shown for simplicity of illustration) including, for example, ruthenium (Ru), tantalum (Ta), titanium (Ti), tungsten (W), iridium (Ir), rhodium (Rh) and platinum (Pt), etc., or mixtures of thereof. Conductive pillars 114 also may include other types of conductive materials, e.g., conductive nitride compounds (TaN, TiN, etc.).

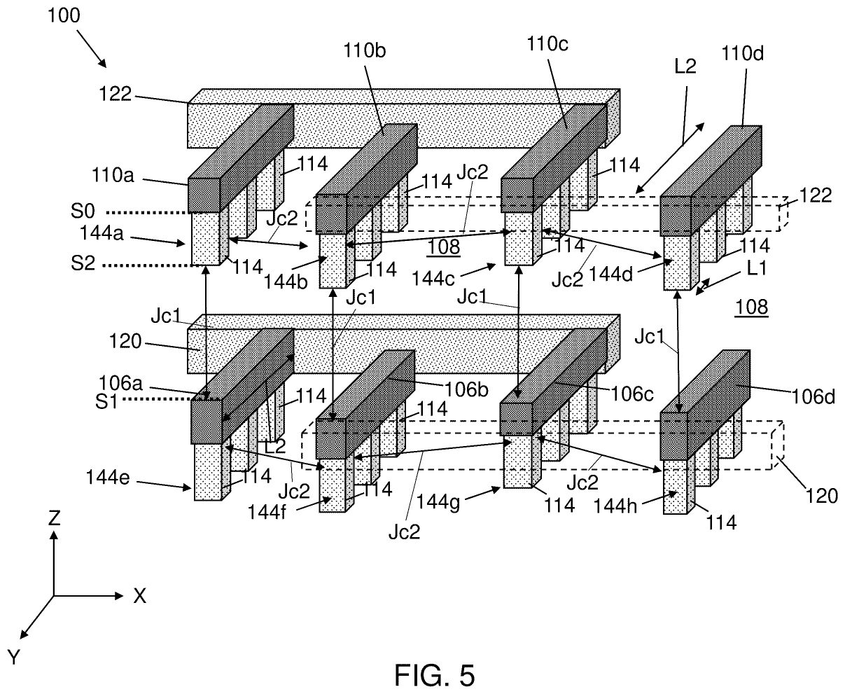

In the case of FIGS. 1 and 2, conductive pillars 114 are below a corresponding first conductive line 106 or second conductive line 110, but conductive pillars 114 alternatively may be in a variety of other locations as shown in FIGS. 5-9 and discussed herein. Conductive pillars 114 may be identified separately herein as 114a, 114b, 114c, 114d, 114e, 114f, 114g, 114h, or collectively as conductive pillars 114. Each conductive pillar 114 may extend vertically through dielectric material 108 only partway between one first conductive line 106 and a vertically aligned second conductive line 110. Second conductive lines 110 each may have a lower surface S0 that is vertically distal to an upper surface S1 of first conductive line 106 thereunder. Conductive pillar 114 may physically interface, i.e., electrically contact, with lower surface S0, and itself may have a lower surface S2 that is between surfaces S1, S2. Thus, lower surface S2 of each conductive pillar 114 does not contact upper surface S1 of first conductive line 106.

Unlike conventional via structures, conductive pillar 114 in embodiments of structure 100 does not conductively couple conductive lines 106, 110 together. A portion of dielectric material 108 remains vertically between conductive pillar 114 and first conductive line 106. In further embodiments discussed herein, dielectric material 108 instead may be vertically between conductive pillar 114 and second conductive line 110, in which case conductive pillar 114 physically interfaces (electrically contacts) with upper surface S1 of second conductive line 110.

In structure 100, the portion(s) of dielectric material 108 between first conductive line 106 (or second conductive line 110) and conductive pillar 114 defines first capacitive junction Jc1 within structure 100. Applying a voltage differential across conductive lines 106, 110 will induce an electric field across dielectric material 108 (and first capacitive junction Jc1), thereby accumulating a net charge on either first conductive line 106 or second conductive line 110 (depending on voltage polarity). During operation, first capacitive junction Jc1 will cause charge to accumulate on any surface one of the two conductive lines 106, 110 that is aligned with conductive pillar 114 through dielectric material 108, thereby providing a capacitor structure for a device. Structure 100 provides multiple capacitive interfaces, in multiple directions. During operation, a second capacitive junction Jc2 between horizontally adjacent conductive pillars conductive lines 106, 110 and conductive pillars 114 will cause charge to accumulate on horizontally adjacent surfaces through dielectric material 108.

Conductive lines 106, 110 in structure 100 may have varying polarities. To function as a high density capacitor, each pair of vertically aligned conductive lines 106, 110 has an opposite polarity. For instance, second conductive line 110a and conductive pillar 114a thereunder may be positively charged, in which case first conductive line 106a therebelow is negatively charged. An adjacent second conductive line 110b and its conductive pillar 114b thereunder may be negatively charged and electrically separated from first conductive line 110a. In this case, first conductive line 106b below conductive pillar 114b may be positively charged. A row of four second conductive lines 110a, 110b, 110c, 110d may have alternating polarities, e.g., second conductive lines 110a, 110c may be positively charged and second conductive lines 110b, 110d may be negatively charged. Conductive pillars 114a, 114b, 114c, 114d thereunder may have the same polarity as their overlying second conductive line 110a, 110b, 110c, 110d by having a conductive physical interface. First conductive lines 106a, 106b, 106c, 106d may have the opposite polarity from their vertically aligned second conductive lines 110a, 110b, 110c, 110d. In this arrangement, structure 100 may provide an alternating polarity metal-insulator-metal (APMIM) capacitor structure. Conductive lines 106, 110 and conductive pillars 114 may provide the two conductive (“metal”) layers for each first capacitive junction Jc1, and dielectric material 108 may provide the insulative layer between the oppositely charged conductive (“metal”) layers. The alternating polarities of horizontally adjacent conductive lines 110a, 110b, 110c, 110d and conductive pillars 114a, 114b, 114c, 114d also allows second capacitive junctions Jc2 to be present therebetween as discussed herein.

To manage the current density in structure 100, each first conductive line 106 optionally may be one of several conductive lines extending horizontally outward from a first conductive wire 120 oriented perpendicularly to first conductive lines 106 and horizontally abutting (electrically contacting) the end of multiple first conductive lines 106. According to the illustrated example, two first conductive wires 120 (one shown in dashed lines in FIG. 1) each may abut and connect to corresponding pairs of first conductive lines 106, i.e., lines 106a, 106c for one first conductive wire 120 and lines 106b, 106d for another first conductive wire 120. Each conductive line 106, 110 may extend horizontally outwardly from its respective conductive wire 106, 110. In this manner, each first conductive wire 120 may be coupled to similarly polarized conductive lines to preserve the alternating polarity arrangement of capacitors. In the same example, two second conductive wires 122 (one shown in dashed lines in FIG. 1) each may abut and electrically connect to corresponding pairs of second conductive lines 110, i.e., lines 110a, 110c for one second conductive wire 122 and lines 110b, 110d for another second conductive wire 122. To prevent electrical shorting from conductive lines 106, 110 to conductive wires 120, 122 having an opposite polarity (and to form second capacitive junction Jc2 therebetween) each conductive line 106, 110 may be horizontally displaced from the opposite polarity conductive wires 120, 122, e.g., along Y-axis as shown. In FIG. 2, several conductive lines 106, 110 are shown in dashed lines to indicate that they are out of plane from the cross-sectional view shown.

Optionally, first conductive lines 106 also may include conductive pillars 114 (individually labeled 114e, 114f, 114g, 114h) thereunder. In some cases, conductive pillars 114 may not necessarily form first capacitive junction Jc1 with any underlying structures (e.g., as shown in FIG. 1), but nonetheless may include second capacitive junction(s) Jc2 with adjacent conductive pillars 114. In the example of FIG. 2, however, a lowermost conductor 128 (FIG. 2 only) may be beneath conductive pillars 114 and first conductive lines 106, thereby defining another first capacitive junction Jc1. Lowermost conductor 128 may not include any conductive pillars 114 coupled thereto, and simply may provide an opposite polarity conductive material beneath ESL 109.

Turning to FIG. 3, structure 100 may include ESLs 109 within or beneath dielectric material(s) 108 in any of a variety of configurations. FIG. 3 provides an example where one ESL 109 extends beneath all of first conductive lines 106 and conductive pillars 114 thereunder, and beneath all of second conductive lines 110 and conductive pillars 114 thereunder. Each ESL 109 is shown by example as having a negligible vertical thickness, but the thickness of ESLs 109 may vary for particular applications. In some cases (e.g., as shown in FIG. 2 and discussed previously), each ESL 109 may extend vertically between lower surface S2 of conductive pillars 114 and upper surface S1 of first conductive lines 106. ESL 109 also may have any desired intermediate thickness, e.g., by controlling the deposition time to form ESL 109 during manufacture. Regardless of ESL 109 thickness, ESL 109 may be in the form of a single layer extending horizontally below all conductive pillars 114, e.g., by depositing one ESL 109 and forming conductive pillars 114 and second conductive lines 110 thereover. In this case, ESL 109 may be a dielectric material, e.g., to retain alternating polarity between the conductive pillars 114a, 114b, 114c, 114d without electrical coupling therebetween.

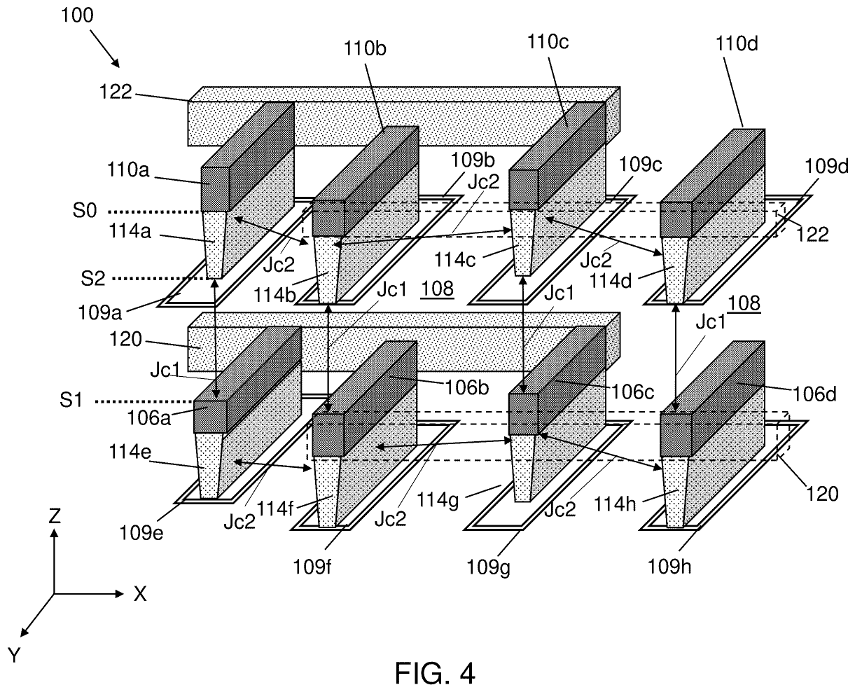

Turning to FIG. 4 further implementations of structure 100 may include multiple distinct ESLs 109, each of which may be positioned beneath only one conductive pillar 114. Each ESL 109 (separately labeled 109a, 109b, 109c, 109d, 109e, 109f, 109g, 109h) may be on dielectric material 108 and beneath a respective conductive pillar 114. Portions of dielectric material 108 may be horizontally between each of the various ESLs 109 in structure 100. ESLs 109 are discontinuous from each other, e.g., in implementations where ESL 109 includes a conductive material, to prevent electrical shorting between conductive pillars 114 through the composition of ESL 109. In some implementations, the possibility of electrical shorting through ESL 109 may be negligible and thus only one ESL 109 may be desired (e.g., as shown in FIGS. 2, 3). Regardless of the shape and size of ESL 109, other aspects of structure 100 may be similar or identical to other embodiments discussed herein.

FIGS. 5-7 depict further implementations of structure 100, in which each first conductive line 106 and each second conductive line 110 vertically interface with a plurality of pillars 144 within dielectric material 108. Each plurality of pillars 144 may include several individual conductive pillars 114, such that each plurality of pillars 144 is arranged as a set of horizontally distinct columns. Each conductive pillar 114 in each plurality of pillars 144 above first conductive lines 106 may physically interface (electrically connect) with lower surface S0 of second conductive lines 110. Each conductive pillar 114 also may have a lower surface S2 that is above upper surface S1 of first conductive lines 106. Where conductive pillars 114 are provided in pluralities 144, each conductive pillar 114 may have a horizontal length L1 (e.g., along Y-axis as shown) that is less than a horizontal length L2 of first conductive line 106 and/or second conductive line 110 thereon. Conductive lines 106, 110 may be of substantially the same length or may have different lengths. Pluralities of pillars 144 may be included in structure 100, e.g., to increase the total number of first capacitive junctions Jc1 between first conductive lines 106 and second conductive lines 110, as well as second capacitive junctions Jc2 between adjacent pillars 114 with opposite polarities, which may affect the total capacitance by changing the surface area distribution of capacitive junctions Jc1, Jc2.

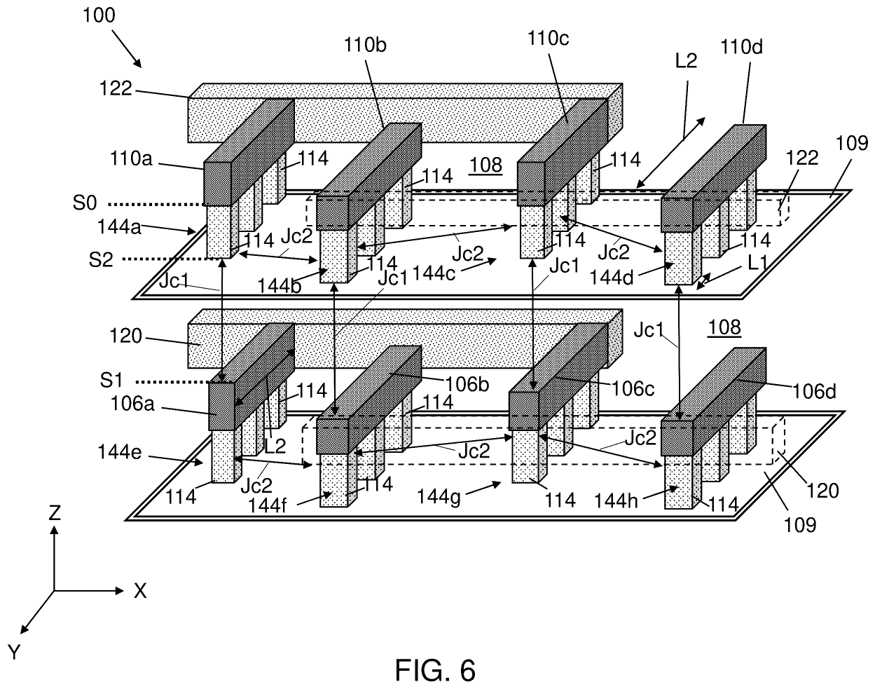

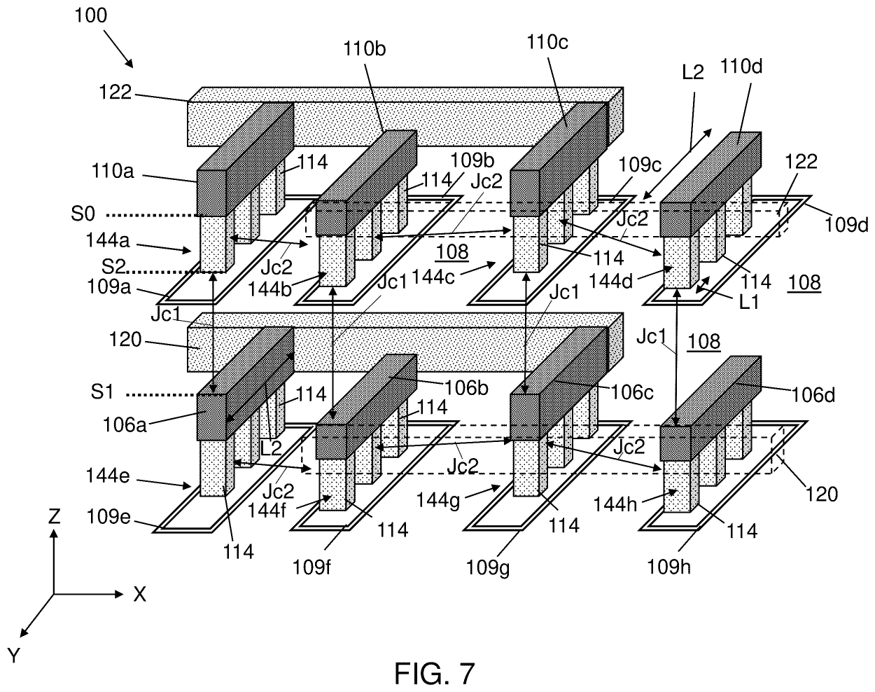

Pluralities of pillars 144 may be combined with other additional or alternative embodiments discussed herein. FIG. 6, for example, includes one ESL 109 located below each plurality of pillars 144 connecting to first conductive lines 106 and another ESL 109 located below each plurality of pillars 144 connecting to second conductive lines 110. Additionally, as shown in FIG. 7, a larger number of separately structured ESLs 109 may be provided such that each plurality of pillars 144 is located on one respective ESL 109. The inclusion and number of ESLs 109 may serve substantially the same technical purposes described relative to other embodiments, e.g., they may increase the capacitance between conductive pillars 114 and conductive line(s) 106, 110. Additionally, the use of distinct ESLs 109 for each plurality of pillars 144 may mitigate the chance of electrical shorting from one plurality of pillars 144 to an adjacent plurality of pillars 144.

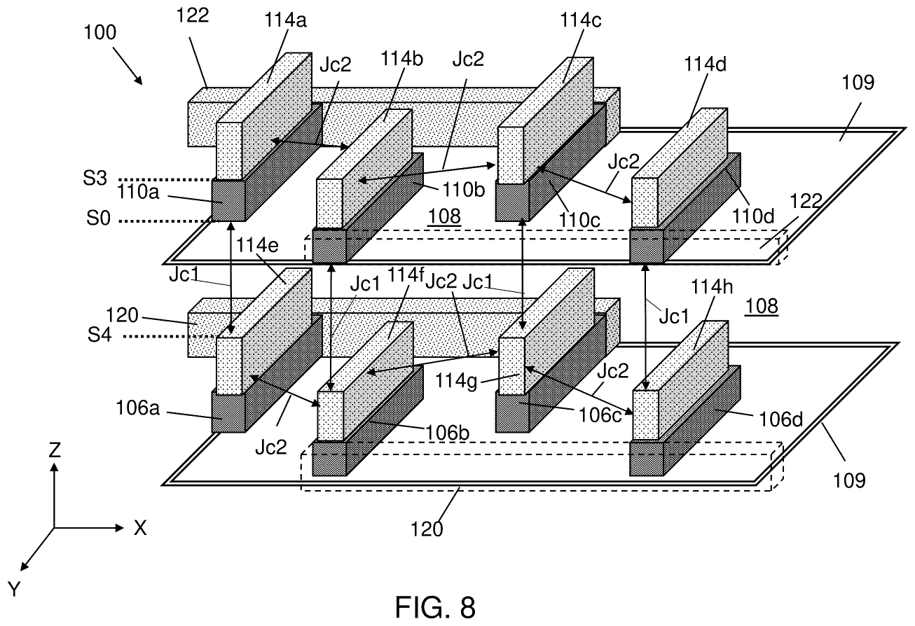

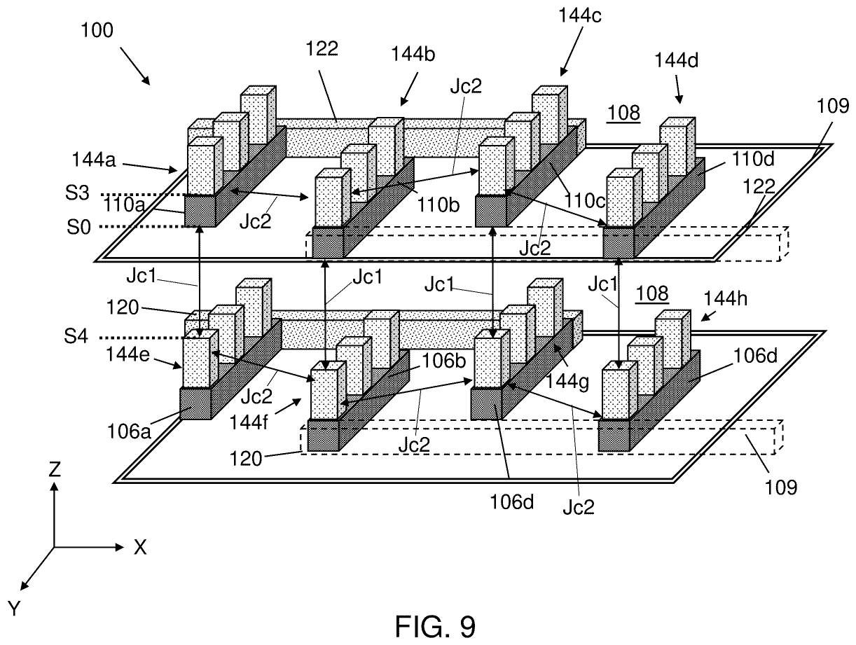

FIGS. 8 and 9 depict still further embodiments of structure 100 in which conductive pillars 114 are positioned on conductive lines 106, 110, such that first capacitive junction Jc1 is vertically between lower surface S0 of second conductive line 110 and an upper surface S4 of one or more conductive pillars 114 thereunder. In this case, a lower surface S3 of each conductive pillar 114 may be on (i.e., land on and electrically connect with) a respective first conductive line 106 or second conductive line 110. The vertical separation distance between lower surface S0 of second conductive line 110 and upper surface S4 of conductive pillar(s) 114 may be less than the distance between lower surface S3 of any conductive pillar(s) 114 on second conductive line 114 and upper surface S4 of underlying conductive pillar(s) 114. No direct physical interface is present between second conductive line 114 and any conductive pillar(s) 114 on first conductive line 106. Thus, first capacitive junction Jc1 is present between conductive lines 110 and pillars 114 instead of a direct physical and electrical interface between the two lines 106, 110 through conductive pillar(s). In addition, second capacitive junction Jc2 remains present between horizontally adjacent oppositely charged pillars 114 and conductive lines 106, 110 in the same layer through dielectric material 108.

Despite the change in position for conductive pillar(s) 114 relative to conductive line(s) 106, 110, structure 100 may be similar to or the same as other embodiments provided herein. For instance, conductive wires 120, 122 may extend perpendicularly relative to conductive line(s) 106, 110 and may be coupled thereto to provide a stem and leaf arrangement or “finger” arrangement of capacitors. The use of multiple conductive wires 120, 122 displaced from each other may allow each adjacent conductive line 106, 110 to have an alternating polarity as discussed elsewhere herein. Additionally, as shown in FIG. 9, conductive pillar(s) 114 may be arranged in pluralities over each conductive line 106, 110 similar to other arrangements discussed herein and shown in FIGS. 5-7. ESL(s) also may be present within each first capacitive junction Jc1, and may be directly beneath each conductive line 106, 110. Although one ESL 109 is shown as an example in FIGS. 8 and 9, multiple ESLs 109 may be included such that each conductive line 106, 110 is located on a respective ESL 109 as provided in other embodiments and discussed herein. ESL 109, in further implementations, may be omitted from any embodiment of structure 100 disclosed herein (e.g., those shown in FIGS. 6-9).

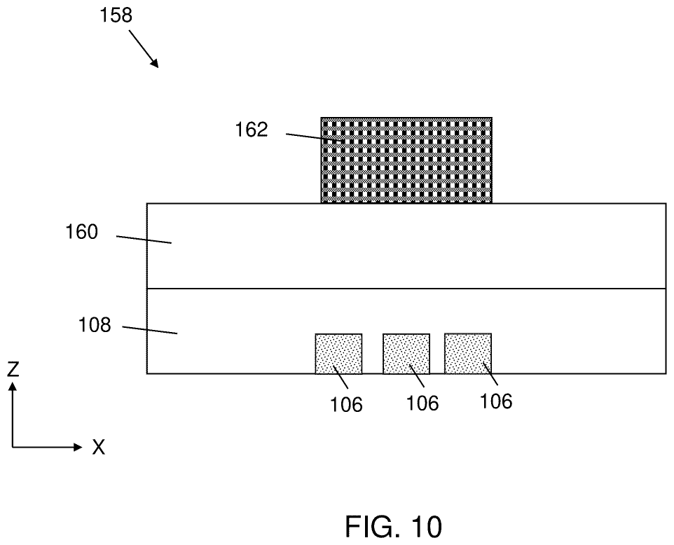

Turning to FIG. 10, the disclosure also include methods to form embodiments of structure 100. FIGS. 10-12 may be implemented to form structure 100 as shown in FIGS. 8, e.g., with conductive pillar(s) 114 on upper surfaces of first conductive lines 106. However, the same processes may be implemented and the resulting structure may be turned upside-down to yield embodiments of structure 100 discussed elsewhere herein, e.g., with second conductive lines 110 directly on, or otherwise physically interfacing with, conductive pillar(s) 114 at their upper surfaces. An initial structure 158 to be processed may include first conductive line 106 (or second conductive line 110) as layers of conductive material (e.g., Cu as discussed herein) within dielectric material 108 and without any pillars coupled thereto. Structure 158 may include an etch stop material 160 (e.g., a nitride-based insulator and/or other insulative materials) on dielectric material 108 and formed over first conductive lines 106 by deposition to any desired thickness. Etch stop material 160 may have an initial thickness that is much larger than the eventual thickness of ESL(s) 109 (FIGS. 2-4, 6-9) in structure 100. Methods of the disclosure may include forming a mask 162 on etch stop material 160, with the size and shape of mask 162 being selected to control the length and width of conductive pillar(s) 114 (FIGS. 1-9) to be formed. Mask 162 may include a developable organic planarization layer (OPL) on the layer to be etched, a developable anti-reflective coating (ARC) layer on the developable OPL, and a photoresist mask layer on the developable ARC layer. In certain implementations, it may be beneficial for the ESL 109 to have a vertical thickness significantly smaller than the vertical thickness of dielectric material 108, e.g., to prevent planarity disturbance and to reduce processing complexity.

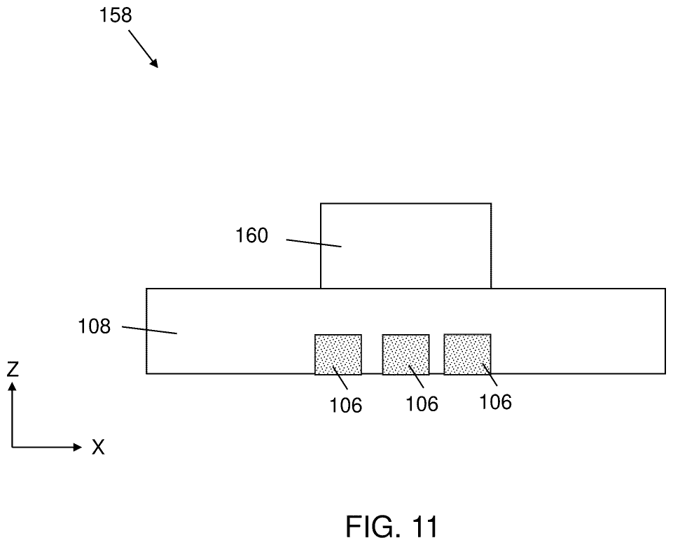

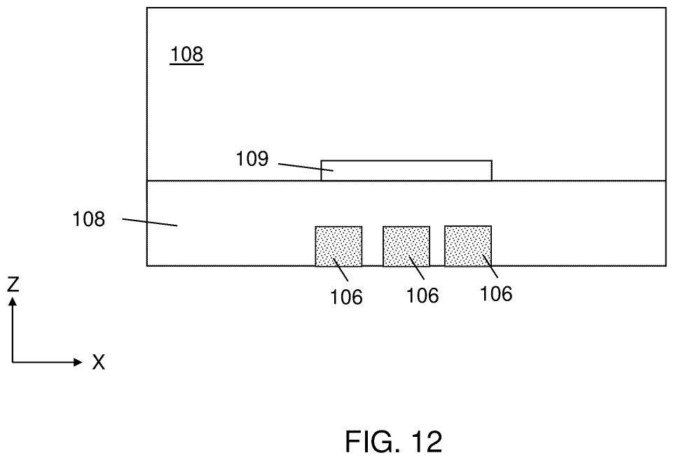

Turning to FIGS. 11-13, further processing may include removing (e.g., by etching) any portions of etch stop material 160 (FIG. 10) not covered by mask 162 (FIG. 10). Mask 162 then can be removed (e.g., by stripping). Portions of etch stop material 160 then can be removed (e.g., by etching), e.g., as shown in FIG. 12. As shown in FIG. 12, a remaining portion of etch stop material 160 remains as ESL 109 on conductive line 106, 110. FIG. 12 also depicts forming an additional portion of dielectric material 108 over ESL 109.

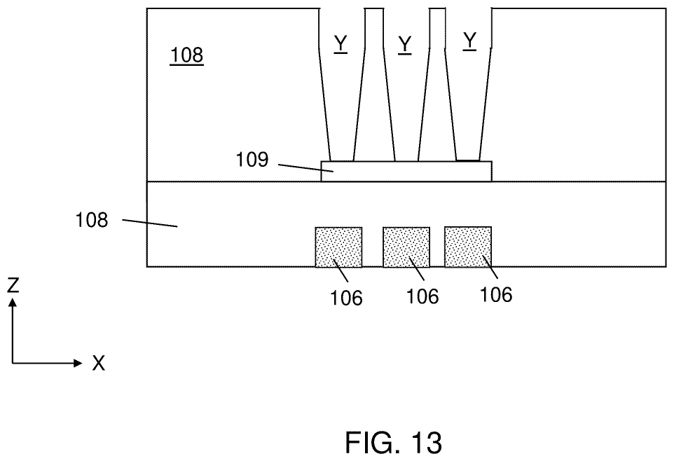

Referring to FIG. 13, further processing may include forming openings Y within dielectric material 108, in which ESL 109 prevents openings Y from extending completely through dielectric materials 108 to expose first conductive lines 106.

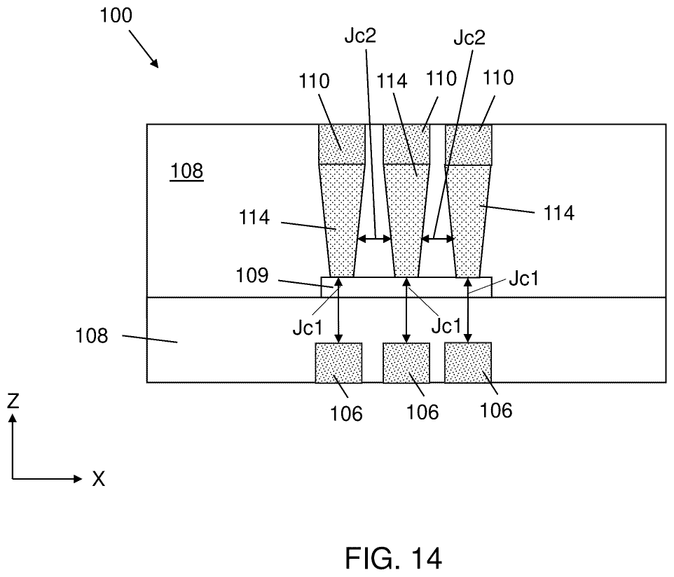

FIG. 14 depicts forming conductive pillar(s) 114, and second conductive lines 110, within openings Y. The forming of conductive pillars 114 and second conductive lines 110 may be by deposition and etching of conductive material within openings Y, and filling (with etch back and/or planarization) of openings Y to form second conductive lines 110 and conductive pillars 114, i.e., they may be formed together. Conductive pillars 114 thus may be vertically above first conductive line 106 and first capacitive junction Jc1 is between each first conductive line 106 and each conductive pillar 114. Second capacitive junctions Jc2 may be horizontally between adjacent conductive pillars 114. Subsequent processing may include, e.g., forming additional conductive line(s) 106, 110, conductive pillar(s) 114 and ESLs 109 over second conductive line 110 to provide additional layers with additional capacitive junctions.

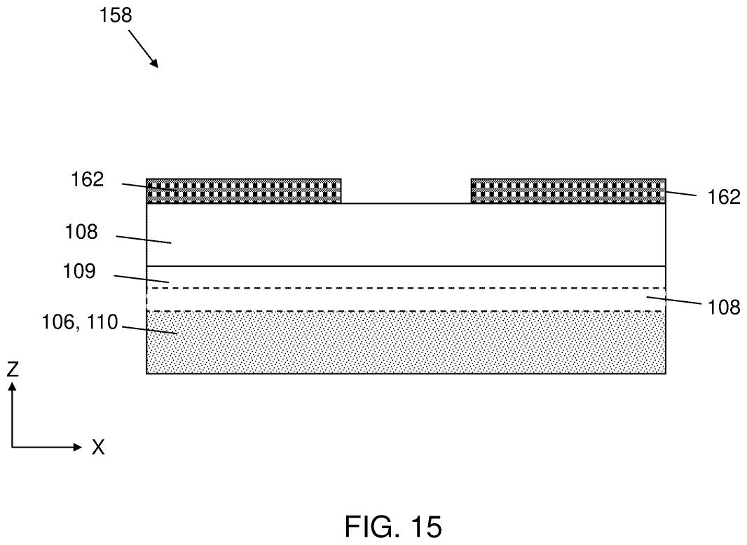

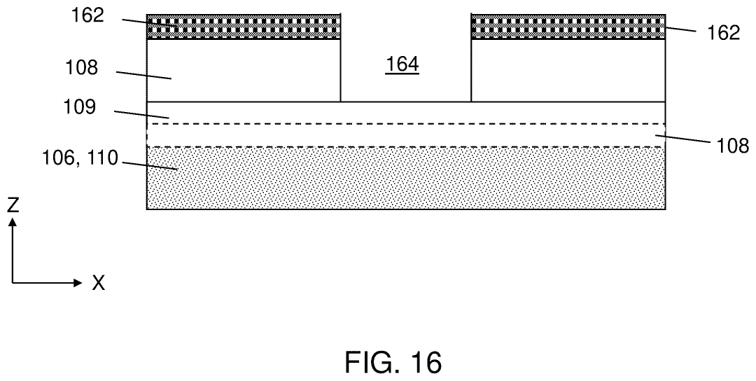

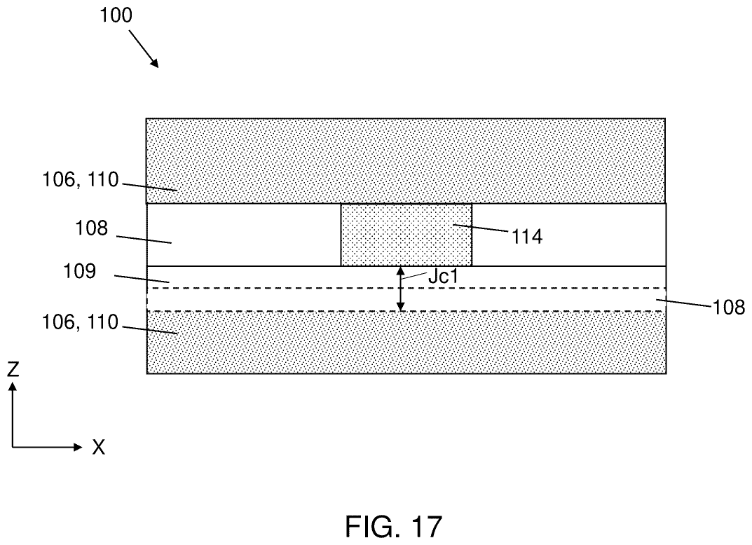

FIGS. 15-17 depict further methods according to the disclosure in which preliminary structure 158 initially includes ESL 109 on conductive line(s) 106, 110 and dielectric material 108 on ESL 109, instead of a single thicker layer of ESL 109. For certain implementations, it may be beneficial to embed the ESL 109 within dielectric material 108 (e.g., within an ILD layer). Such an implementation is shown in FIGS. 15-17 through a portion of dielectric material 108 under ESL 109 and indicated with dashed lines. Embedding of ESL 109 within dielectric material 108 may reduce capacitance variability and, in some cases, may help to resist dielectric breakdown during operation. By this approach, methods of the disclosure include forming an opening 164 (FIG. 16 only) within dielectric material 108 (e.g., by etching with mask 162 in place) to the depth of ESL 109. Opening 164 then may be filled with conductive material to provide conductive pillar 114. Any excess material outside opening 164 can then be removed (e.g., by chemical mechanical planarization (CMP) or similar techniques, and another conducive line 106, 110 then may be formed on conductive pillar 114. The example implementation shown in FIGS. 15-17 may be suitable for embodiments of structure 100 where second conductive line 110 is on an upper surface conductive pillar 114. Alternatively, products created by the implementation shown in FIGS. 15-17 may be turned upside down to provide an embodiment of structure where conductive pillar 114 is on an upper surface of first conductive line 106.

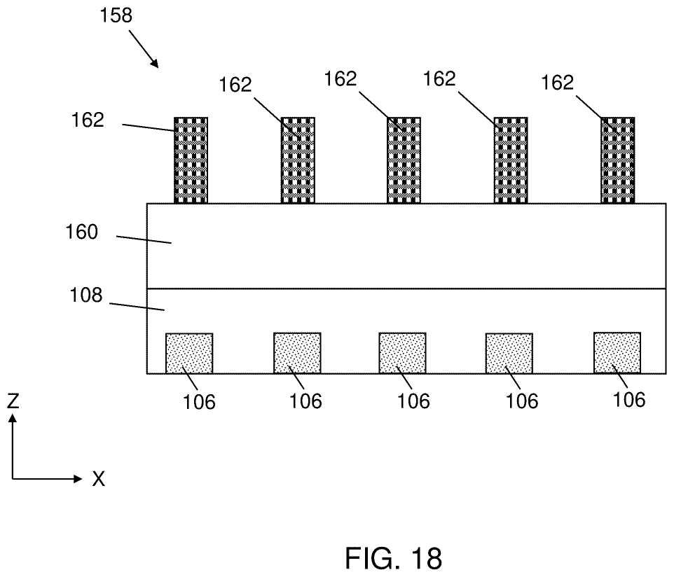

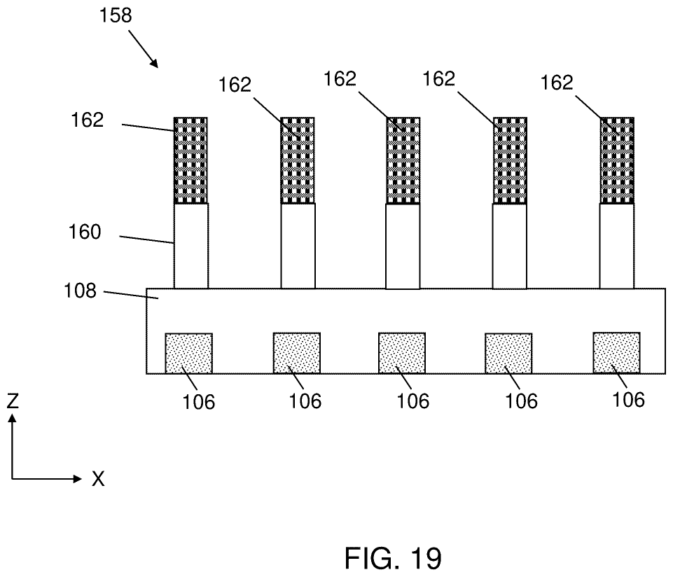

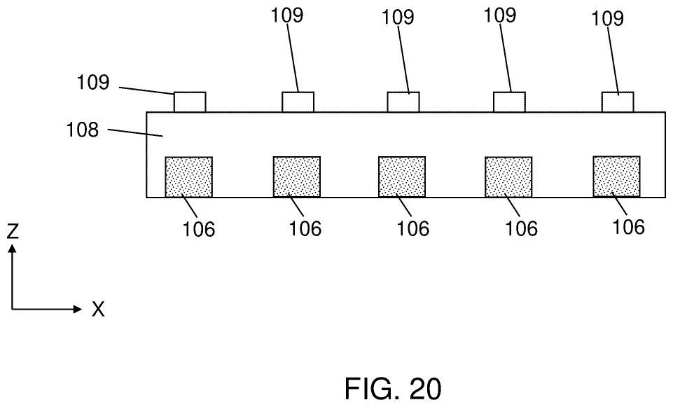

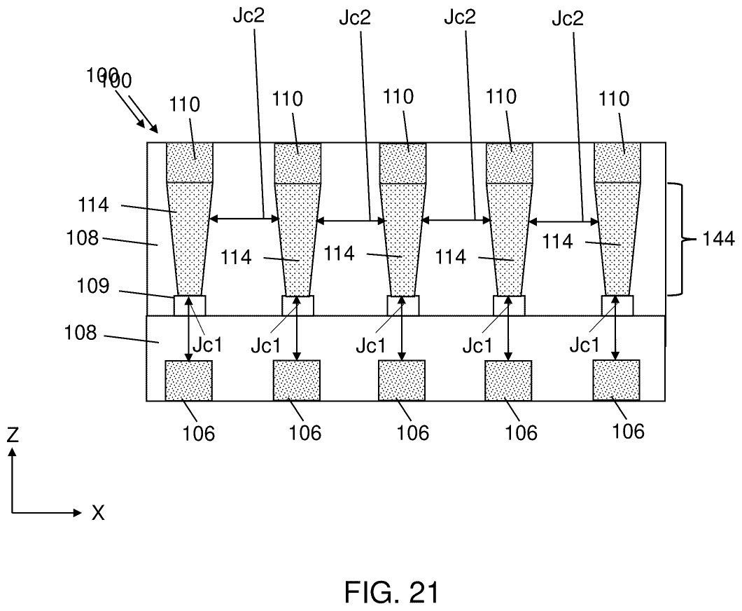

Referring now to FIGS. 18-21, methods of the disclosure may include changing the number of masks 162 on etch stop material 160, e.g., to provide a plurality of conductive pillars 144 (FIGS. 14, 15) on conductive line(s) 106. FIGS. 18-21 illustrate forming structure 100 as shown in FIGS. 9, e.g., with plurality of conductive pillar(s) 144 on upper surfaces of first conductive lines 106. However, the same processes may be implemented and the resulting structure may be turned upside-down to yield embodiments of structure 100 discussed elsewhere herein, e.g., with second conductive lines 110 directly on, or otherwise physically interfacing with, plurality of conductive pillar(s) 144 at upper surface of each conductive via 114. A similar or identical set of processing steps may be implemented with additional masks 162 with different horizontal dimensions to form any desired number of conductive pillars 114 on conductive line(s) 106, 110. Collectively, the conductive pillars 114 provide plurality of pillars 144. As discussed elsewhere herein, individual ESLs 109 may be formed e.g., by removing only a portion of etch stop material 160 on dielectric material 108. The remaining etch stop material 160 thereby provides ESL 109 on dielectric material 108. Conductive pillars 114 then may be formed, e.g., by forming dielectric material 108 over ESLs 109, forming openings (not shown) therein to expose ESLs 109, and forming conductive materials within the openings to form conductive pillars 114 and second conductive lines 110. These processes may be implemented as many times as desired to provide first capacitive junctions Jc1 between successive metal wiring layers. In still further embodiments, the size and number of masks(s) 162 may be changed in each implementation to provide a different shape, size, or number of conductive pillar(s) 114 and/or ESLs 109 in successive layers.

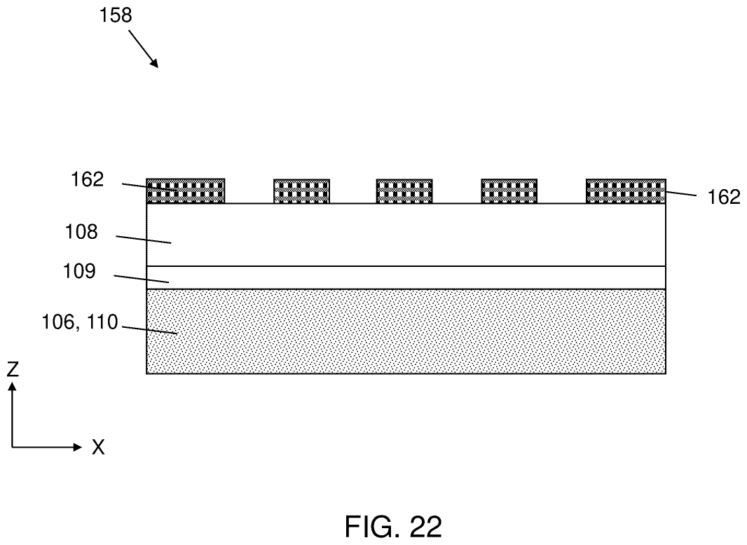

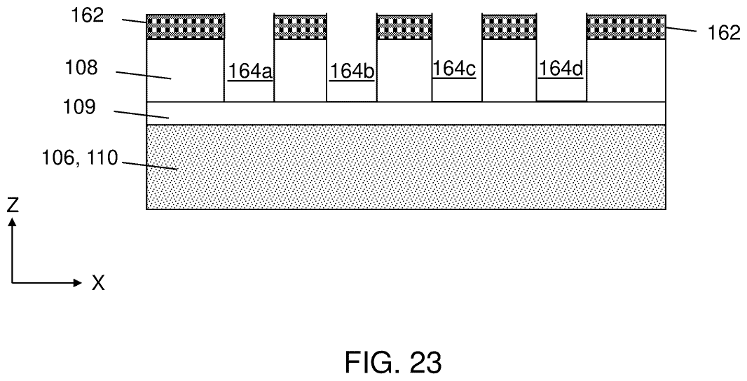

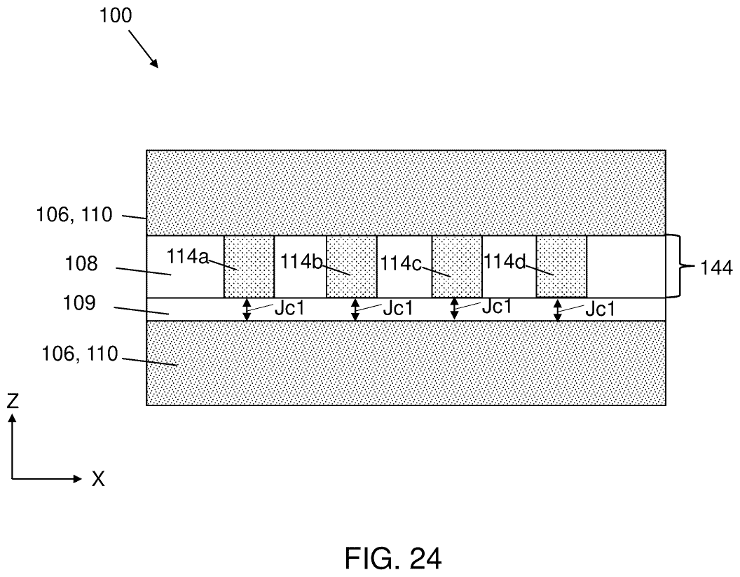

FIGS. 22-24 depict further methods according to the disclosure in which preliminary structure 158 initially includes ESL 109 on conductive line(s) 106, 110 and dielectric material 108 on ESL 109, instead of a single thicker layer of ESL 109. By this approach, methods of the disclosure include forming multiple openings 164a, 164b, 164c, 164d (FIG. 23 only) within dielectric material 108 (e.g., by etching with mask 162 in place) to the depth of ESL 109. Opening 164 then may be filled with conductive material to provide plurality of conductive pillars 144. Any excess material outside openings 164a, 164b, 164c, 164d can then be removed (e.g., by chemical mechanical planarization (CMP) or similar techniques, and another conducive line 106, 110 then may be formed on plurality of conductive pillars 144. The example implementation shown in FIGS. 22-24 implementation may be for embodiments of structure 100 where second conductive line 110 is on an upper surface of plurality of conductive pillars 144. Alternatively, in such an implementation, the resulting product may be turned upside down to provide an embodiment of structure where plurality of conductive pillars 144 is on an upper surface of first conductive line 106.

Embodiments of the disclosure provide various technical and commercial advantages, examples of which are discussed herein. Among other things, structure 100 may provide improvements in capacitive density as compared to conventional capacitors formed in metal wiring layers and/or device layers. In some cases, e.g., where pluralities of pillars 144 are present between conductive lines 106, 110, the capacitive density may improve by sixty percent or more relative to conventional devices. In turn, this reduces surface area required to provide a desired number of capacitors within a device structure. In addition to these and other technical benefits, embodiments of the disclosure are capable of providing APMIM capacitor arrangements simply by including multiple conductive wires 120, 122 coupled to alternating conductive lines 106, 110 in structure 100.

The structure and method as described herein are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the,” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a first conductive line within a dielectric material, the dielectric material extending over the first conductive line;
a second conductive line within the dielectric material and substantially vertically aligned with the first conductive line; and
a conductive pillar within the dielectric material between the first conductive line and the second conductive line, wherein the conductive pillar includes one of an upper surface contacting a lower surface of the second conductive line and a lower surface contacting an upper surface of the first conductive line, wherein a vertical thickness of the conductive pillar is less than a vertical thickness between the first conductive line and the second conductive line, a first capacitive junction is between the conductive pillar and one of the first conductive line and the second conductive line.

2. The structure of claim 1, wherein the first conductive line and the second conductive line are each one of a plurality of conductive lines extending horizontally outward from a conductive wire.

3. The structure of claim 1, wherein the conductive pillar is one of a plurality of pillars within the dielectric material, each of the plurality of pillars having a horizontal length less than a horizontal length of the first conductive line or the second conductive line.

4. The structure of claim 1, wherein the dielectric material includes an etch stop layer (ESL) vertically between the conductive pillar and one of the first conductive line and the second conductive line.

5. The structure of claim 4, wherein the ESL vertically interfaces with the conductive pillar and each of a plurality of additional conductive pillars between the first conductive line and the second conductive line.

6. The structure of claim 4, wherein the dielectric material further includes an inter-level dielectric (ILD) layer on the ESL, the ILD layer having a different composition from the ESL.

7. The structure of claim 6, wherein the ILD layer includes silicon carbonitride (SiCN).

8. The structure of claim 1, wherein a second capacitive junction is between the conductive pillar and a horizontally adjacent conductive pillar.

9. A structure comprising:
a first plurality of conductive lines within a dielectric material, each of the first plurality of conductive lines having an alternating polarity relative to an adjacent conductive line of the first plurality of conductive lines;
a second plurality of conductive lines on the dielectric material and substantially vertically aligned with the first plurality of conductive lines, each of the second plurality of conductive lines having an alternating polarity relative to an adjacent conductive line in the second plurality of conductive lines; and
a plurality of conductive pillars within the dielectric material, wherein each of the plurality of conductive pillars includes one of an upper surface interfacing with a lower surface of the second plurality of conductive lines and a lower surface interfacing with an upper surface of the first plurality of conductive lines conductive line, a vertical thickness of each conductive pillar is less than a vertical thickness between the plurality of first conductive lines and the plurality of second conductive lines, a first capacitive junction is between each conductive pillar and one of the first plurality of conductive lines and the second plurality of conductive lines, and a second capacitive junction is between two horizontally adjacent conductive pillars of the plurality of conductive pillars.

10. The structure of claim 9, further comprising:
a first conductive wire coupled to the first plurality of conductive lines, wherein each of the first plurality of conductive lines extends horizontally outwardly from the first conductive wire; and
a second conductive wire coupled to the second plurality of conductive lines, wherein each of the second plurality of conductive lines extends horizontally outwardly from the second conductive wire.

11. The structure of claim 9, wherein the dielectric material includes an etch stop layer (ESL) vertically between each of the plurality of conductive pillars and the respective first conductive line or the respective second conductive line.

12. The structure of claim 11, wherein the dielectric material further includes an inter-level dielectric (ILD) layer on the ESL, the ILD layer having a different composition from the ESL.

13. The structure of claim 12, wherein the ILD layer includes silicon carbonitride (SiCN).

14. The structure of claim 9, wherein a material composition of the plurality of conductive pillars is different from a material composition of the first plurality of conductive lines or the second plurality of conductive lines.

15. A method comprising:
forming a first conductive line within a dielectric material;
forming a conductive pillar within the dielectric material over the first conductive line, wherein a vertical thickness of the conductive pillar is less than a vertical thickness of the dielectric material between the first conductive line and the second conductive line; and
forming a second conductive line on the dielectric material and the conductive pillar above the first conductive line, wherein the second conductive line is substantially aligned with the first conductive line, a first capacitive junction is between the conductive pillar and one of the first conductive line and the second conductive line.

16. The method of claim 15, wherein a second capacitive junction is between the conductive pillar and a horizontally adjacent conductive pillar.

17. The method of claim 15, wherein forming the conductive pillar includes forming a plurality of pillars within the dielectric material, each of the plurality of pillars having a horizontal length less than a horizontal length of the first conductive line or the second conductive line.

18. The method of claim 15, wherein forming the dielectric material includes forming an etch stop layer (ESL) vertically between the conductive pillar and one of the first conductive line and the second conductive line.

19. The method of claim 18, wherein the ESL vertically interfaces with the conductive pillar and each of a plurality of additional conductive pillars between the first conductive line and the second conductive line.

20. The method of claim 18, wherein forming the dielectric material further includes forming an inter-level dielectric (ILD) layer on the ESL, the ILD layer having a different composition from the ESL.
